(19) United States
(12) Patent Application Publication
(10) Pub. No.: US 2003/0155613 A1
(43) Pub. Date: Aug. 21, 2003

(54) Semiconductor device and method of manufacturing the same

(76) Inventors: Hisashi Hasegawa, Chiba-shi (JP); Jun Osanai, Chiba-shi (JP); Takayuki Okamoto, Chiba-shi (JP)

Correspondence Address: ADAMS & WILKS, 31st Floor, 50 Broadway, New York, NY, 10004, US

(21) Appl. No.: 10/354,571

(22) Filed: Jan. 30, 2003

(30) Foreign Application Priority Data
Feb. 19, 2002 (JP) 2002-041403
Jan. 16, 2003 (JP) 2003-007858

(51) Int. Cl. H01L 27/01

(52) U.S. Cl. 257/347

(57) ABSTRACT

A semiconductor device structure using an SOI substrate is provided along with a method of manufacturing the structure, and the structure makes it possible to reduce parasitic capacitance while preventing the parasitic bipolar effect caused by the floating substrate effect and preventing supporting substrate bias from changing the threshold voltage. The semiconductor device using an SOI substrate is characterized in that a P-well diffusion layer or an N-well diffusion layer is formed only in a body region located below a gate electrode in a semiconductor thin film.

### BACKGROUND OF THE INVENTION

1. Field of the Invention

The present invention relates to a MOS field effect transistor having an SOI (silicon on insulator) structure.

2. Description of the Related Art

A MOS transistor formed on an SOI substrate, unlike one formed on a bulk silicon substrate, is characterized in that thorough element isolation is possible and that parasitic capacitance such as junction capacitance can be reduced. These characteristics lead to such advantages as high speed operation, less power consumption, and high integration level.

A conventional structure of this MOS transistor using an SOI substrate is shown in FIG. 19. According to the conventional structure, a P-well diffusion layer 105 or an N-well diffusion layer 106 is formed throughout the entire transistor element forming region of a semiconductor thin film 104 and, after a gate insulating film and a gate electrode are formed, N+ or P+ source region and drain region are formed by ion implantation (See JP 11-26769 A (pp. 2-3, FIG. 1), for example).

Parasitic capacitance of a MOS transistor using an SOI substrate includes source and drain junction capacitance. In order to reduce source and drain junction capacitance, it is necessary for the bottoms of source and drain diffusion layers, or a depletion layer that is formed by pn junction between the source and drain diffusion layers and wells, to reach a buried insulating film. This replaces depletion layer capacitance at the bottom of the source and drain diffusion layers with buried insulating film capacitance, and the junction capacitance is thus reduced.

In some cases, the MOS transistor using an SOI substrate takes a structure in which the concentration in a well region is raised and a structure in which the semiconductor thin film is increased in thickness to suite the device needed. These structures can solve problems such as kinks by floating substrate effect, namely, parasitic bipolar effects, which are prominent in the MOS transistor using an SOI substrate, and a change in threshold voltage due to supporting substrate bias unique to SOI substrates.

However, in the conventional MOS transistor in which a well is formed throughout the entire element formation region of a semiconductor thin film, increased impurity concentration in a well or a semiconductor thin film with an increased thickness might prevent the bottoms of source and drain diffusion layers, or a depletion layer that is formed by pn junction between the source and drain diffusion layers and wells, from reaching a buried insulating film. As a result, the transistor fails to reduce the source and drain capacitance and the benefits of the SOI structure MOS transistor are lost.

### SUMMARY OF THE INVENTION

The present invention has been made in view of the above, and an object of the present invention is therefore to reduce problems such as parasitic bipolar effects and influence of supporting substrate bias as well as to provide a MOS transistor having a structure that can overcome those problems and reduce parasitic capacitance.

In order to solve the above-mentioned problems, the present invention employs the following measures.

There is provided a semiconductor device characterized by including a MOS transistor which uses an SOI (silicon on insulator) substrate and which includes a semiconductor supporting substrate, a buried insulating film, and a semiconductor thin film, the buried insulating film being formed on the semiconductor supporting substrate, the semiconductor thin film being formed on the buried insulating film, in which the MOS transistor has a well only in a body region below a gate electrode in the semiconductor thin film.

### BRIEF DESCRIPTION OF THE DRAWINGS

In the accompanying drawings:

FIG. 1 is a structural sectional view showing Embodiment 1 of a semiconductor device with an SOI substrate according to the present invention;

FIG. 2 is a structural sectional view showing Embodiment 2 of a semiconductor device with an SOI substrate according to the present invention;

FIGS. 3A and 3B show an embodiment of the present invention and FIG. 3A is a plan view of a T-shaped gate structure NMOS transistor whereas FIG. 3B is a sectional view taken along the line A-A′ in FIG. 3A;

FIGS. 4A and 4B show an embodiment of the present invention and FIG. 4A is a plan view of an H-shaped gate structure NMOS transistor whereas FIG. 4B is a sectional view taken along the line B-B′ in FIG. 4A;

FIGS. 5A to 5C show an embodiment of the present invention and FIG. 5A is a plan view of a source-body tie structure NMOS transistor whereas FIG. 5B is a sectional view taken along the line C-C′ in FIG. 5A and FIG. 5C is another plan view showing a structure different from the one in FIG. 5A;

FIG. 6 is a structural sectional view showing Embodiment 3 of a semiconductor device with an SOI substrate according to the present invention;

FIG. 7 is a structural sectional view showing Embodiment 4 of a semiconductor device with an SOI substrate according to the present invention;

FIG. 8 is a structural sectional view showing Embodiment 5 of a semiconductor device with an SOI substrate according to the present invention;

FIG. 9 is a structural sectional view showing Embodiment 6 of a semiconductor device with an SOI substrate according to the present invention;

FIG. 10 is a structural sectional view showing Embodiment 7 of a semiconductor device with an SOI substrate according to the present invention;

FIG. 11 is a structural sectional view showing Embodiment 8 of a semiconductor device with an SOI substrate according to the present invention;

FIGS. 12A to 12G are process sectional views showing an embodiment of a method of manufacturing the semiconductor device of Embodiment 1 according to the present invention;

FIGS. 13A to 13F are process sectional views showing another embodiment of the method of manufacturing the semiconductor device of Embodiment 1 according to the present invention;

FIGS. 14A to 14E are process sectional views showing an embodiment of a method of manufacturing the semiconductor device of Embodiment 3 according to the present invention;

FIGS. 15A to 15G are process sectional views showing an embodiment of a method of manufacturing the semiconductor device of Embodiment 4 according to the present invention;

FIGS. 16A to 16G are process sectional views showing an embodiment of a method of manufacturing the semiconductor device of Embodiment 5 according to the present invention;

FIGS. 17A to 17E are process sectional views showing an embodiment of a method of manufacturing the semiconductor device of Embodiment 6 according to the present invention;

FIGS. 18A to 18E are process sectional views showing an embodiment of a method of manufacturing the semiconductor device of Embodiment 7 according to the present invention; and

FIG. 19 is a structural sectional diagram of a conventional semiconductor device using an SOI substrate.

### DETAILED DESCRIPTION OF THE PREFERRED EMBODIMENTS

Detailed descriptions are given below on embodiments of the present invention with reference to the accompanying drawings.

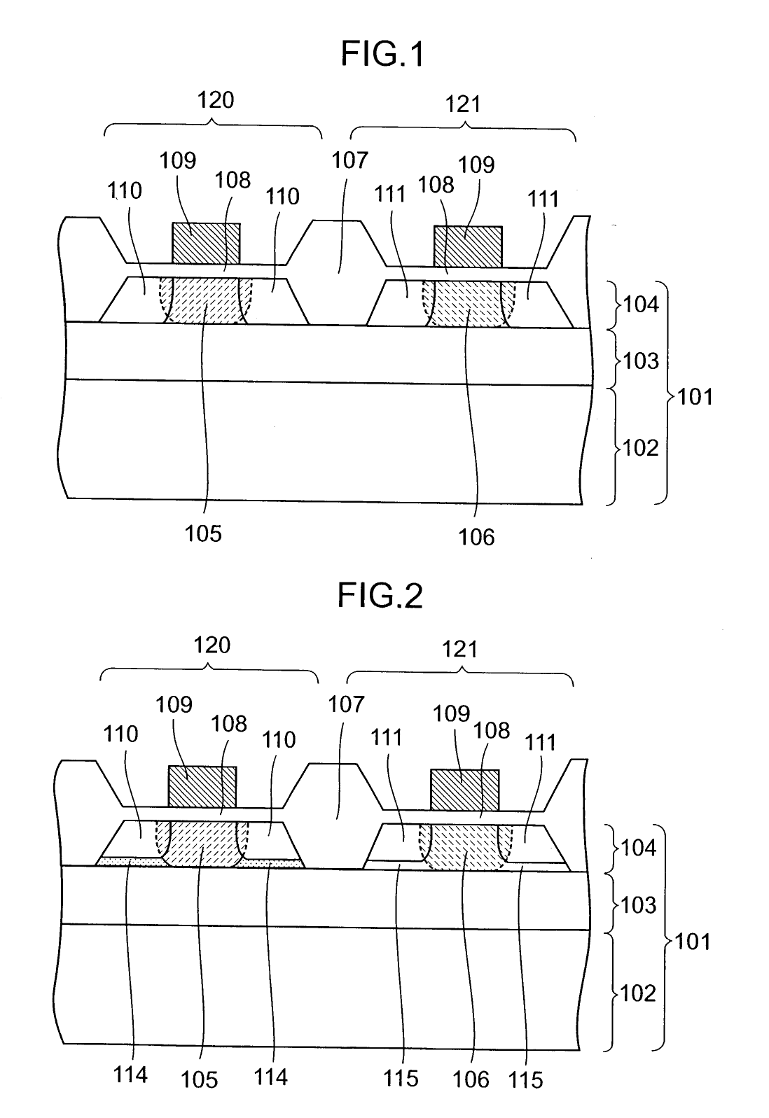

FIG. 1 is a sectional view of a semiconductor device using an SOI substrate and shows an embodiment of a first structure of the present invention.

An SOI substrate 101 has a three-layer structure consisting of a p type semiconductor supporting substrate 102, a buried insulating film 103, and a p type semiconductor thin film 104 for forming an element. The p type semiconductor supporting substrate 102 and the p type semiconductor thin film 104 are insulated from each other by the buried insulating film 103.

The p type semiconductor thin film 104 in FIG. 1 has an NMOS transistor 120 (hereinafter referred to as NMOS) and a PMOS transistor 121 (hereinafter referred to as PMOS) formed therein. The NMOS 120 has N+ diffusion layers 110, which contain an impurity in high concentration and which serve as a source and a drain, forming a so-called single drain structure. Similarly, the PMOS 121 has P+ diffusion layers 111, which contain an impurity in high concentration, forming the single drain structure. In each of the NMOS 120 and PMOS 121, a gate electrode is formed from an N+ polycrystalline silicon film 109 on a gate insulating film 108. In the semiconductor thin film, an area below the gate electrode is called a body region. A P-well diffusion layer 105 is formed only in the body region of the NMOS 120 and an N-well diffusion layer 106 is formed only in the body region of the PMOS 121. The NMOS 120 and the PMOS 121 are electrically insulated from their surroundings by a field insulating film 107 that is formed by LOCOS (local oxidation of silicon).

When a well is formed only in a body region below a gate electrode, a deeper source-drain diffusion layer can be obtained than when a well is formed throughout the semiconductor thin film. This is because a well formed only in a body region allows regions where a source and a drain are formed in a later step to keep the initial substrate concentration of the semiconductor thin film and the initial substrate concentration is lower than the concentration in the well. As an example, consider a case in which the entire NMOS forming region in a 0.4 μm thick semiconductor thin film 104 of an SOI substrate receives ion implantation to set the P-well concentration to 2.0×10¹⁵ atoms/cm³. If the ion implantation employs arsenic, for example, with the dose set to 5×10¹⁵ atoms/cm² to form N+ diffusion layers 110 that are to serve as a source and drain of an NMOS, then the obtained N+ diffusion layers are merely about 0.25 μm deep (although it may vary depending on what heat treatment is given after the ion implantation). However, N+ diffusion layers deep enough to reach a buried insulating film can be obtained by avoiding ion implantation of the P-well in the source and drain forming regions and forming the source and the drain later using arsenic.

Element isolation may be achieved by shallow trench isolation (STI) in which an insulating film is buried to form a field insulating film as shown in FIG. 11, instead of LOCOS shown in FIG. 1.

FIG. 2 is a sectional view of a semiconductor device using an SOI substrate and shows an embodiment of a second structure of the present invention. In FIG. 2, the bottoms of N+ diffusion layers 110 of an NMOS 120 do not reach a buried insulating film. However, depletion layers 114 that are formed by pn junction reach the buried insulating film and make it possible to provide the same effect as the structure of FIG. 1. By forming a well 105 only in a part of the NMOS 120, regions for forming a source and a drain are allowed to keep the initial substrate concentration that is lower than the concentration in the P-well and, therefore, the depletion layers 114 that are low concentration regions can extend far. Accordingly, the depletion layers 114 are readily made deep enough to reach the buried insulating film 103 and the junction capacitance can be reduced.

In the PMOS 121 too, its P+ diffusion layers 111 that contain an impurity in high concentration do not reach the buried insulating film 103. However, the P+ diffusion layers 111 are formed in P-substrate regions 115 and therefore it is obvious that regions for forming a source and a drain are automatically joined to the buried insulating film.

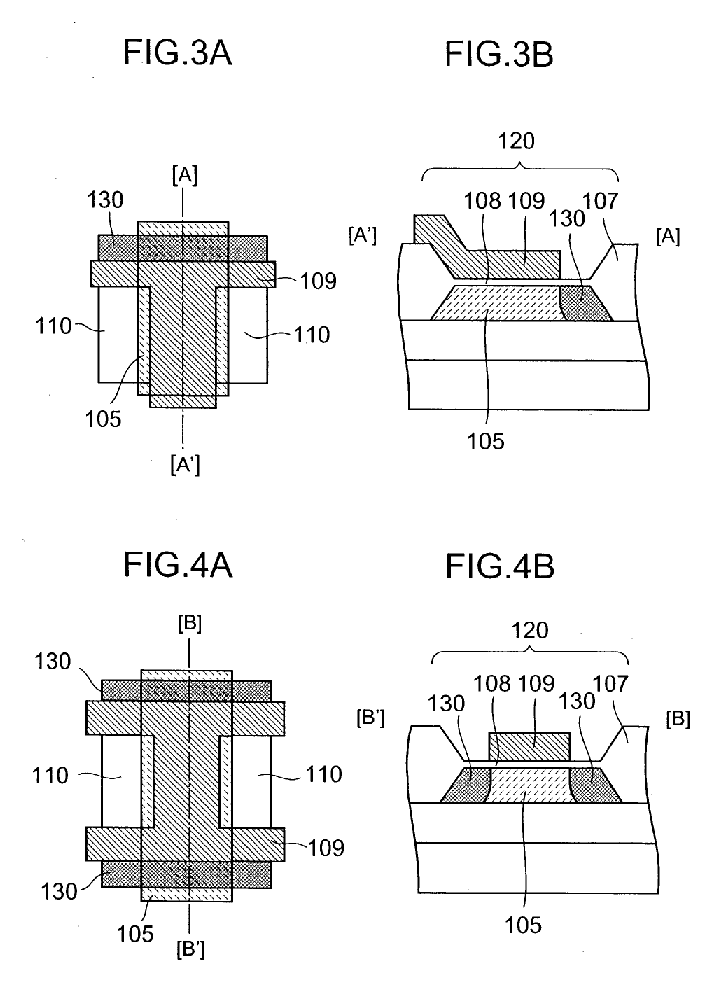

FIGS. 3A and 3B show an embodiment of a planar structure of a semiconductor device with an SOI substrate according to the present invention. FIG. 3A is a plan view of an NMOS transistor. In FIG. 3A, an N+ polycrystalline silicon film 109 serving as a gate electrode takes a T-shaped structure and extends toward the source region and the drain region on one end thereof in the W length direction (along the line [A]-[A′]). A P+ body contact region 130 is formed on one end in the W length direction of the MOS transistor beyond the gate electrode. FIG. 3B is a sectional view taken along the line [A]-[A′] in FIG. 3A. A P-well diffusion layer 105 in FIG. 3A is formed only in a portion for forming a channel except below the portions of the T-shaped N+ polycrystalline silicon film 109 that extend toward the source and drain regions, and there is no P-well diffusion layer in N+ diffusion layers 110 that are to serve as the source region and the drain region. Desirably, the P-well diffusion layer 105 is formed so as to overlap the N+ polycrystalline silicon film 109 in the source and drain directions by about 2 μm at most. The P+ body contact region 130 is necessary in a partially depleted (PD) structure MOS transistor, where its body region is not fully depleted and a part of the body region is a neutral region, in order to fix the electric potential of the body region, but whether or not the P-well diffusion layer 105 overlaps the body contact region 130 does not make a difference. On the opposite side, namely, on the side [A′], the P-well diffusion layer 105 overlaps a bird's beak region on a LOCOS edge in order to reduce a parasitic channel called a hump.

The description given here on the NMOS also applies to the PMOS.

FIGS. 4A and 4B show another embodiment of the planar structure of the semiconductor device with an SOI substrate according to the present invention. FIG. 4A is a plan view of an NMOS transistor. In FIG. 4A, an N+ polycrystalline silicon film 109 serving as a gate electrode takes an H-shaped structure and extends toward the source region and the drain region on both ends thereof in the W length direction (the line [B]-[B′]). A P+ body contact region 130 is formed on either end in the W length direction of the MOS transistor beyond the gate electrode. FIG. 4B is a sectional view taken along the line [B]-[B′] in FIG. 4A. Similar to FIGS. 3A and 3B, a P-well diffusion layer 105 in FIGS. 4A and 4B is formed only in a portion for forming a channel except below the portions of the H-shaped N+ polycrystalline silicon film 109 that extend toward the source and drain regions, and there is no P-well diffusion layer in N+ diffusion layers 110 that are to serve as the source region and the drain region. It is desirable to form the P-well diffusion layer 105 in a way that makes the layer 105 overlap the N+ polycrystalline silicon film 109 by about 2 μm at most, similar to FIGS. 3A and 3B. Whether or not the P-well diffusion layer 105 overlaps the body contact region 130 does not make a difference. The description given here on the NMOS also applies to the PMOS.

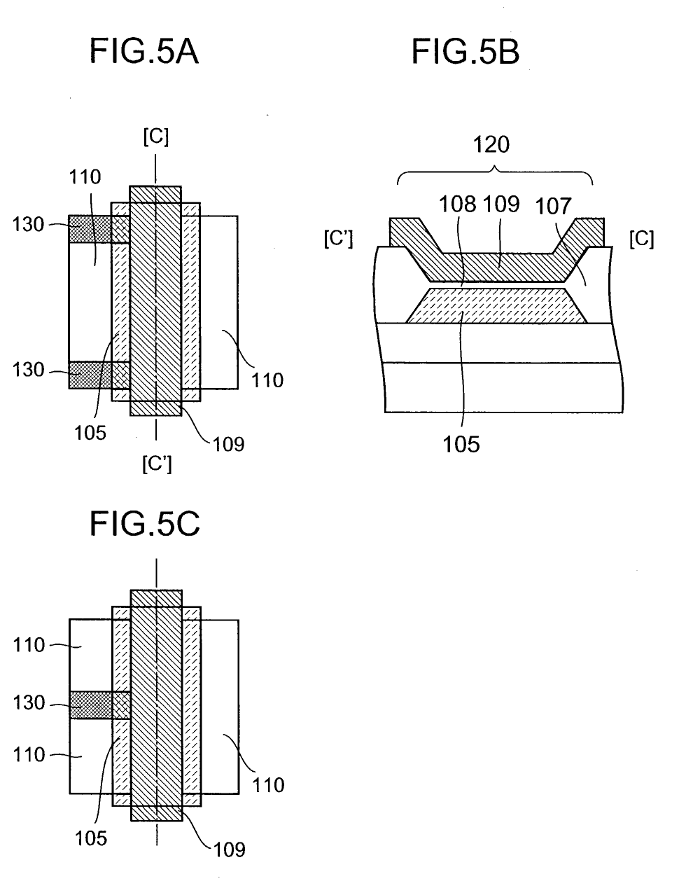

FIGS. 5A to 5C show, as another structure that has a body contact region, still another embodiment of the planar structure of the semiconductor device with an SOI substrate according to the present invention. FIG. 5A is a plan view of a source-body tie structure in which a P+ body contact region 130 is formed on either end in the W length direction of one of N+ diffusion layers 110 that serves as a source region. FIG. 5B is a sectional view taken along the line [C]-[C′] in FIG. 5A.

In the source-body tie structure, the P+ body contact region 130 can be arranged freely on the source side by using a mask. Therefore the position of the P+ body contact region can be changed to suit the need. For example, the layout in FIG. 5C may be employed. In the source-body tie structure too, a P-well diffusion layer is formed only in a portion for forming a channel and there is no P-well diffusion layer in the N+ diffusion layers that are to serve as the source region and the drain region. Similar to FIGS. 3A and 3B, the P-well diffusion layer overlaps a LOCOS edge in the W direction in order to reduce a parasitic channel called a hump.

The description given here on the NMOS also applies to the PMOS.

It is understood through the above descriptions that a well diffusion layer formed only in a body region below a gate electrode of a MOS transistor makes it easy to form N+ diffusion layers and P+ diffusion layers, or a depletion layer resulted from pn junction, deep enough to reach a buried insulating film and thereby reduce parasitic capacitance. This is effective particularly when the concentration of the well is raised or the semiconductor thin film is increased in thickness in order to reduce parasitic bipolar operation caused by the floating substrate effect and to reduce influence of supporting the so-called substrate bias that causes electric potential difference between the semiconductor supporting substrate and the body. Thus the present invention is capable of reducing parasitic bipolar effects and influence of supporting substrate bias while keeping parasitic capacitance low.

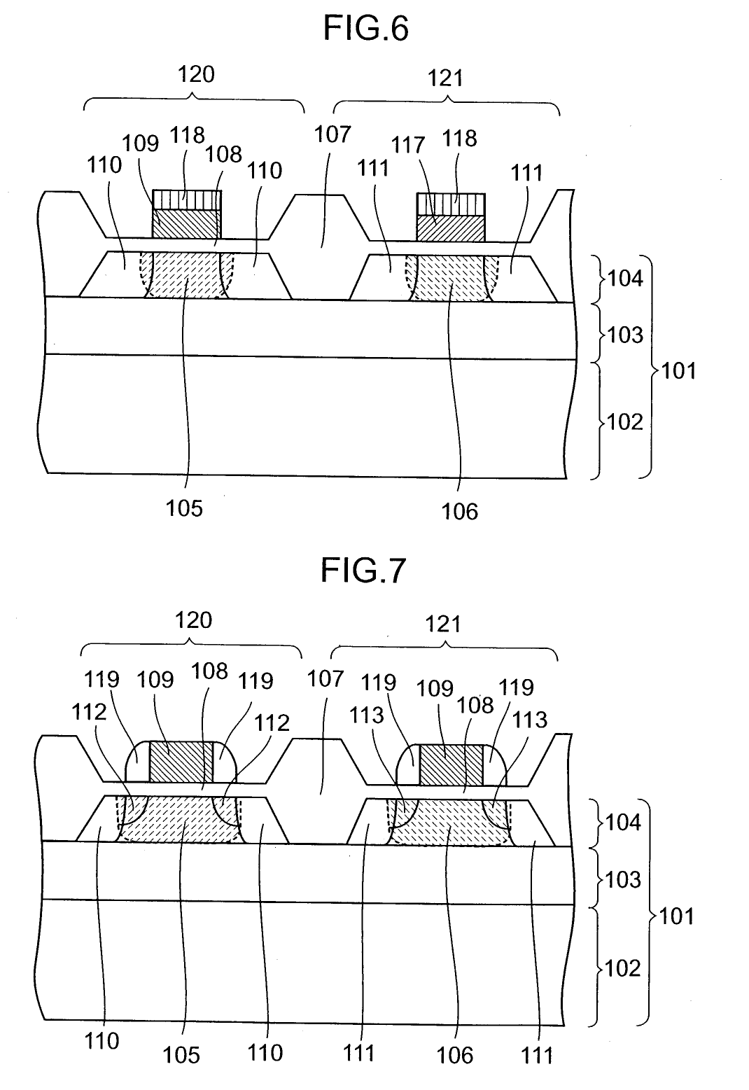

FIG. 6 is a sectional view showing an embodiment of a third structure of the present invention. Similar to FIG. 1 showing Embodiment 1, FIG. 6 has a semiconductor thin film 104 surrounded by a buried insulating film 103 and a field insulating film 107 to form therein an NMOS 120 and a PMOS 121 which have the partial well structure.

FIG. 6 is different from FIG. 1 in that FIG. 6 employs a so-called homopolar gate technique which gives a gate electrode of the NMOS 120 the n type conductivity and a gate electrode of the PMOS 121 the p type conductivity. The NMOS 120 and the PMOS 121 are front-channel MOS transistors. It is a common knowledge that the sub-threshold characteristic of a front-channel MOS transistor is not degraded much even when the threshold voltage is small and that it can accordingly operate with lower voltage while consuming less power. The gate electrode of the NMOS 120 has a laminate structure consisting of an N+ polycrystalline silicon film 109 and a high melting point metal silicide film 118. The film 118 is obtained by depositing tungsten silicide or the like on the film 109. The PMOS 121 also has a polycide gate structure, and the gate electrode is a laminate of a P+ polycrystalline silicon film 117 and a high melting point metal silicide film 118 that is obtained similarly by depositing tungsten silicide or the like on the film 117. Other than tungsten silicide, molybdenum silicide, titanium silicide, platinum silicide, or the like can be used.

By selectively forming a well below a gate electrode in accordance with the present invention, this structure too can provide the same effect that in as FIG. 1.

Although not shown in the drawing, element separation may be achieved by STI instead of LOCOS.

FIG. 7 is a sectional view showing an embodiment of a fourth structure of the present invention. Similar to FIG. 1 showing Embodiment 1, FIG. 7 has a semiconductor thin film 104 surrounded by a buried insulating film 103 and a field insulating film 107 to form therein an NMOS 120 and a PMOS 121 which have the partial well structure (meaning 120 and 121 each has a well below its gate electrode that is formed from an N+ polycrystalline silicon film 109).

This embodiment employs an LDD (lightly doped drain) structure in which sources and drains of the NMOS 120 and PMOS 121 have N− diffusion layers 112 and P− diffusion layers 113 for relieving electric field, and the gate electrodes are formed from the N+ polycrystalline silicon film 109. Side spacers 119 composed of an insulating film are formed on side walls of the N+ polycrystalline silicon film 109 that serve as the gate electrodes, thereby securing the N− diffusion layers and the P− diffusion layers. This LDD structure shown in FIG. 7 is advantageous in making the gate length more minute and improving the reliability of a gate oxide film. By selectively forming a well diffusion layer below a gate electrode in accordance with the present invention, this structure too can provide the same effect as that in FIG. 1.

Although not shown in the drawing, element separation may be achieved by STI instead of LOCOS.

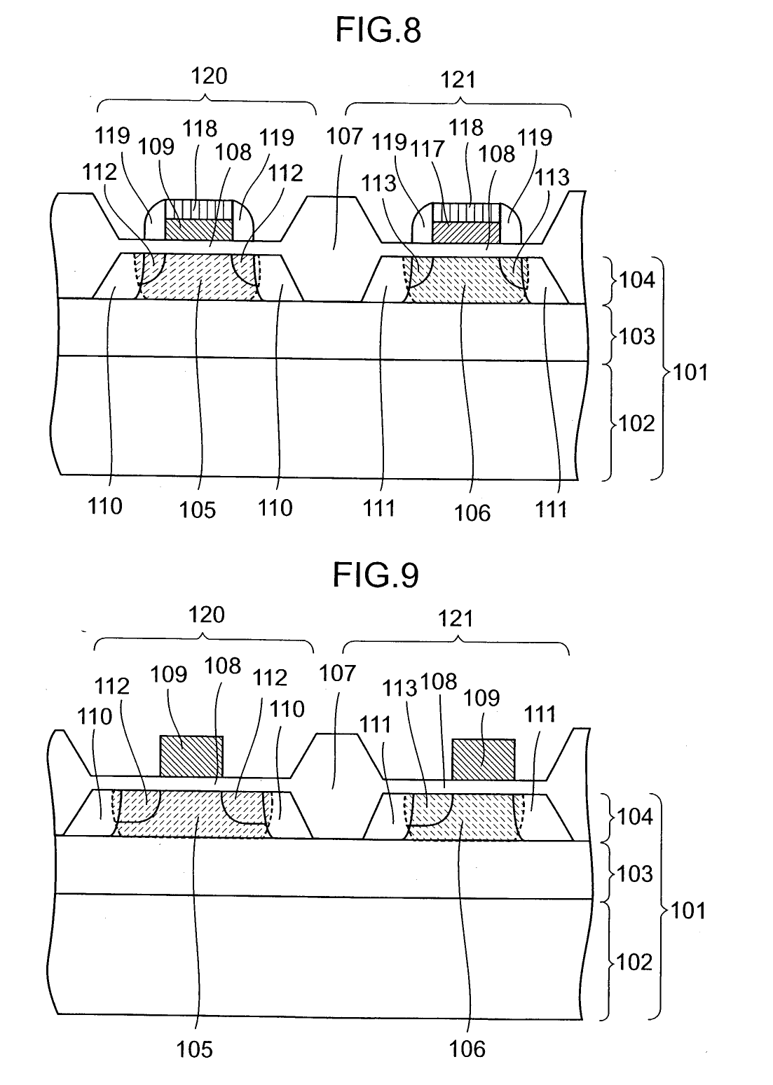

FIG. 8 is a sectional view showing an embodiment of a fifth structure of the present invention. Similar to FIG. 7, this embodiment employs an LDD structure in which sources and drains of an NMOS 120 and PMOS 121 have N− diffusion layers 112 and P− diffusion layers 113 for relieving electric field. In FIG. 8, a gate electrode of the NMOS 120 has a laminate structure consisting of an N+ polycrystalline silicon film 109 and a high melting point metal silicide film 118. The film 118 is obtained by depositing tungsten silicide or the like on the film 109. The PMOS 121 also has a polycide gate structure, and its gate electrode is a laminate of a P+ polycrystalline silicon film 117 and a high melting point metal silicide film 118 that is obtained similarly by depositing tungsten silicide or the like on the film 117. Similar to FIG. 6, the MOS transistors of FIG. 8 can operate with lower voltage while consuming less power owing to the homopolar gate technique and can operate at high speed because of their polycide structure. Other than tungsten silicide, molybdenum silicide, titanium silicide, platinum silicide, or the like can be used.

Side spacers 119 composed of an insulating film are formed on side walls of the gate electrodes, there by securing the N− diffusion layers and the P− diffusion layers. By selectively forming a well diffusion layer below a gate electrode in accordance with the present invention, the structure shown in FIG. 8 too can provide the same effect as that in FIGS. 1, 6, and 7.

Although not shown in the drawing, element separation may be achieved by STI instead of LOCOS.

FIG. 9 is a sectional view showing an embodiment of a sixth structure of the present invention. Similar to FIG. 1 showing Embodiment 1, FIG. 9 has a semiconductor thin film 104 surrounded by a buried insulating film 103 and a field insulating film 107 to form therein an NMOS 120 and a PMOS 121 which have the partial well structure (meaning 120 and 121 each has a well below its gate electrode that is formed from an N+ polycrystalline silicon film 109). FIG. 9 is different from FIG. 1 in that the NMOS and PMOS in FIG. 9 have a drain extension structure in order to improve channel length modulation in an analog circuit, prevent hot carriers from lowering the reliability of a gate insulating film and others, and improve the drain withstand voltage. In the drain extension structure, N− diffusion layers 112 and P− diffusion layers 113, which have low impurity concentration, are formed in sources and drains, or drains alone, and N+ diffusion layers 110 and P+ diffusion layers 111, which have high impurity concentration, are formed in sources and drains, or drains alone, apart from the gate electrodes.

The distance between a gate electrode and a high concentration impurity diffusion layer, namely, offset length, is usually 0.5 μm or more and less than 10 μm, though it depends on the input voltage. In FIG. 9, only the drain side of the PMOS 121 takes the offset structure whereas both the drain and source take the offset structure in the NMOS 120. In accordance with the use of a MOS transistor in a circuit, a structure suited to the circuit can be chosen for the MOS transistor irrespective of the conductivity type of the MOS transistor. As a standard case, when a current flows in both directions and a source and a drain are switched as the need arises, the withstand voltage is necessary in both directions and therefore the source and the drain both take the offset structure. When a current flows only in one direction and switching between a source and a drain is not necessary, only one side, namely, the drain side alone, takes the offset structure in order to reduce parasitic resistance.

The present invention is applicable to the offset MOS structure of FIG. 9 too, in other words, a well diffusion layer can be formed in a part of a transistor of FIG. 9 to provide the same effect as that in FIG. 1.

Although not shown in the drawing, element separation may be achieved by STI instead of LOCOS.

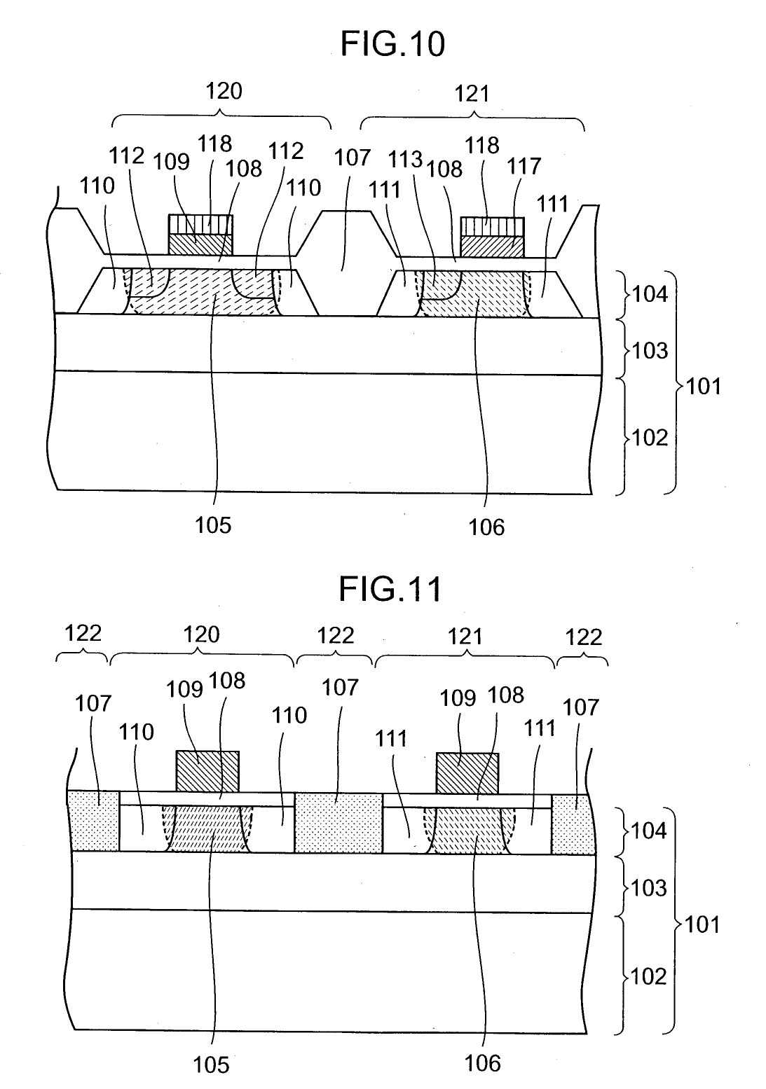

FIG. 10 is a sectional view showing an embodiment of a seventh structure of the present invention. Similar to FIG. 9, sources and drains, or drains alone, of an NMOS 120 and PMOS 121 take the offset structure in this embodiment. In FIG. 10, a gate electrode of the NMOS 120 has a laminate structure consisting of an N+ polycrystalline silicon film 109 and a high melting point metal silicide film 118. The film 118 is obtained by depositing tungsten silicide or the like on the film 109. The PMOS 121 also has a polycide gate structure, and its gate electrode is a laminate of a P+ polycrystalline silicon film 117 and a high melting point metal silicide film 118 that is obtained similarly by depositing tungsten silicide or the like on the film 117. Similar to FIGS. 6 and 8, the MOS transistors of FIG. 10 can operate with lower voltage while consuming less power owing to the homopolar gate technique and can operate at high speed because of their polycide structure. Other than tungsten silicide, molybdenum silicide, titanium silicide, platinum silicide, or the like can be used.

By selectively forming a well diffusion layer below a gate electrode in accordance with the present invention, the structure shown in FIG. 10 too can provide the same effect as that in FIGS. 1, 6, and 9.

Although not shown in the drawing, element separation may be achieved by STI instead of LOCOS.

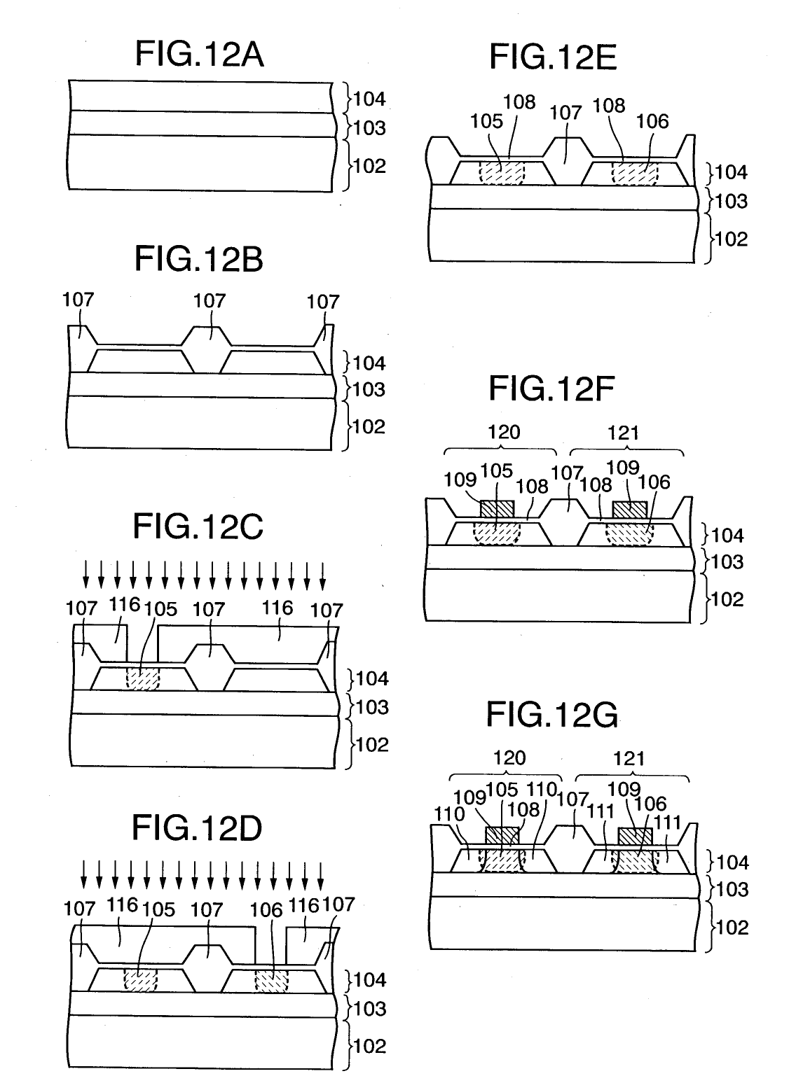

FIGS. 12A to 12G illustrate an embodiment of a method of manufacturing the semiconductor device shown in FIG. 1. A semiconductor substrate 101 shown in FIG. 12A is a p type SOI substrate assembled by bonding, and a buried insulating film 103 is used to insulate a p type semiconductor supporting substrate 102 and a p type semiconductor thin film 104 from each other. The p type substrate concentration is in general about 1×10¹⁴ to 1×10¹⁵ atoms/cm³.

As shown in FIG. 12B, a field insulating film 107 is formed on the semiconductor substrate 101 by LOCOS. The thickness of the field insulating film 107 is determined by the thickness of the semiconductor thin film since it is necessary to join the field insulating film 107 with the buried insulating film 103 in order to isolate elements.

Although not shown in the drawing, shallow trench isolation (STI) may be employed for element isolation instead of LOCOS. In STI, the field insulating film is formed by etching the semiconductor thin film 104 and burying an insulating film.

Thereafter, a photoresist is applied and the resultant photoresist film 116 is exposed to light as shown in FIG. 12C. Then a P-well region of an NMOS is patterned and a P-well diffusion layer 105 is formed by ion implantation. Similarly, an N-well region of a PMOS receives patterning by photolithography and ion implantation as shown in FIG. 12D to form an N-well diffusion layer 106. The substrate at this point is shown in FIG. 12E. To form wells, the P-well diffusion layer 105 is obtained by ion implantation of boron or BF₂as p type impurity and the N-well diffusion layer 106 is obtained by ion implantation of phosphorus as an n type impurity.

The P-well diffusion layer and the N-well diffusion layer are formed only in body regions below gate electrodes, which are subsequently formed from an N+ polycrystalline silicon film 109 as shown in FIG. 12F. A detailed description is given here on the positional relation of the P-well diffusion layer 105 and N-well diffusion layer 106 to their respective gate electrodes that are formed in the subsequent step from the N+ polycrystalline silicon film 109. When too small areas of the P-well diffusion layer 105 and N-well diffusion layer 106 overlap their respective gate electrodes, it leaves initial substrate regions to affect the threshold voltage and other factors. On the other hand, when too large areas of the P-well diffusion layer 105 and N-well diffusion layer 106 overlap their respective gate electrodes, the wells extend to portions that are to form source regions and drain regions and make it difficult for the source regions and the drain regions, or a depletion layer resulted from pn junction, to reach the buried insulating film. Accordingly, taking into account mask misalignment and influence of thermal diffusion, the P-well diffusion layer 105 and the N-well diffusion layer 106 desirably overlap their respective gate electrodes by 2 μm or less.

Next, a gate insulating film 112 is formed by thermal oxidation and ions are implanted to adjust the threshold voltage. Thereafter, polycrystalline silicon is deposited onto the entire surface by CVD (chemical vapor deposition). The resultant polycrystalline silicon film receives pre-deposition of phosphorus to assume the n type conductivity and form the N+ polycrystalline silicon film. Then a photoresist pattern is formed and etched to form gate electrodes 109 from the N+ polycrystalline silicon film. The substrate at this point is shown in FIG. 12F.

After the gate electrodes are formed, an NMOS 120 receives ion implantation of an n type impurity, phosphorus or arsenic, to form N+ diffusion layers 110 that are to serve as a source region and a drain region as shown in FIG. 12G. A PMOS 121 receives ion implantation of a p type impurity, boron or BF₂, to form P+ diffusion layers 111 that are to serve as a source and drain of the PMOS. The impurity concentration in each of the source regions and drain regions is generally about 5×10¹⁹ to 1×10²¹ atoms/cm³. The subsequent steps are not shown in the drawing but are identical with those of a usual MOS transistor manufacturing process; an interlayer insulating film is formed by deposition, contact holes are formed, a metal wire is formed, and then a protective film is formed to cover the substrate and complete a semiconductor device that has the structure shown in FIG. 1. In the case where STI is employed, the semiconductor device is structured as shown in FIG. 11.

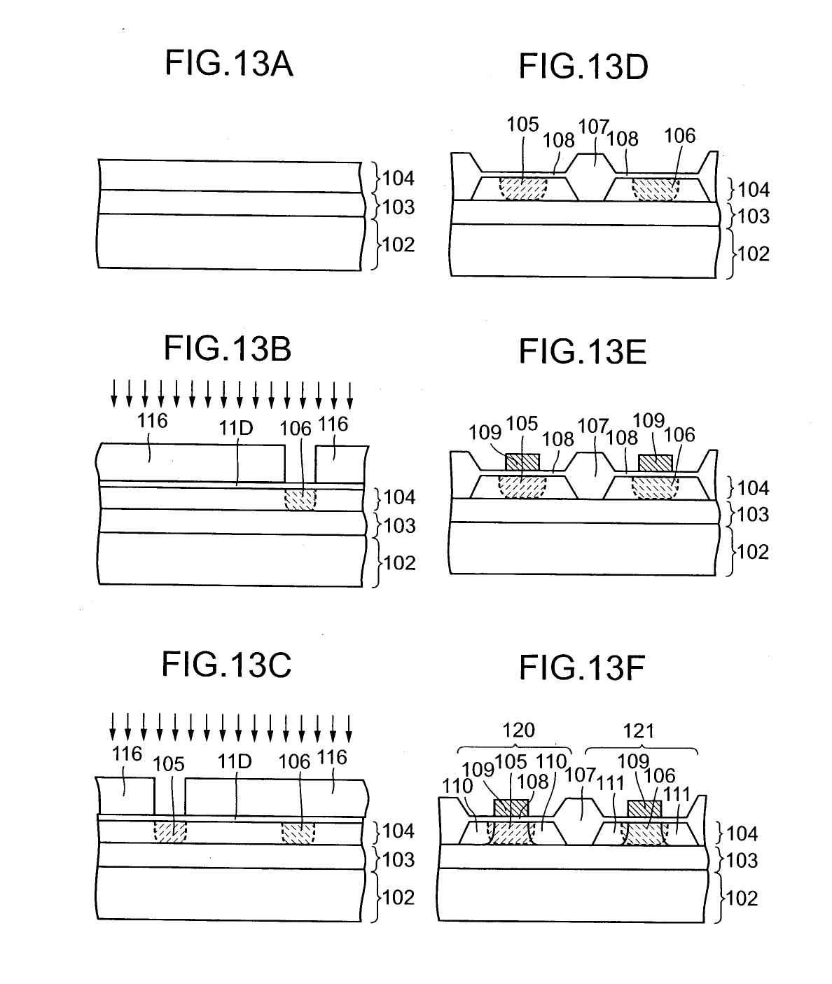

FIGS. 13A to 13F show another embodiment of the method of manufacturing the semiconductor device of FIG. 1. This embodiment is different from the one illustrated in FIGS. 12A to 12G in that the well diffusion layers are formed before the field insulating film 107 is formed. The field insulating layer 107 here is formed after the N-well diffusion layer 106 and the P-well diffusion layer 105 are formed as shown in FIGS. 13B and 13C. The subsequent steps are identical with those of the process illustrated in FIGS. 12A to 12G. Although not shown in the drawing, this manufacturing process may be modified so that the field insulating film is formed after the N-well diffusion layer is formed and before the P-well diffusion layer is formed.

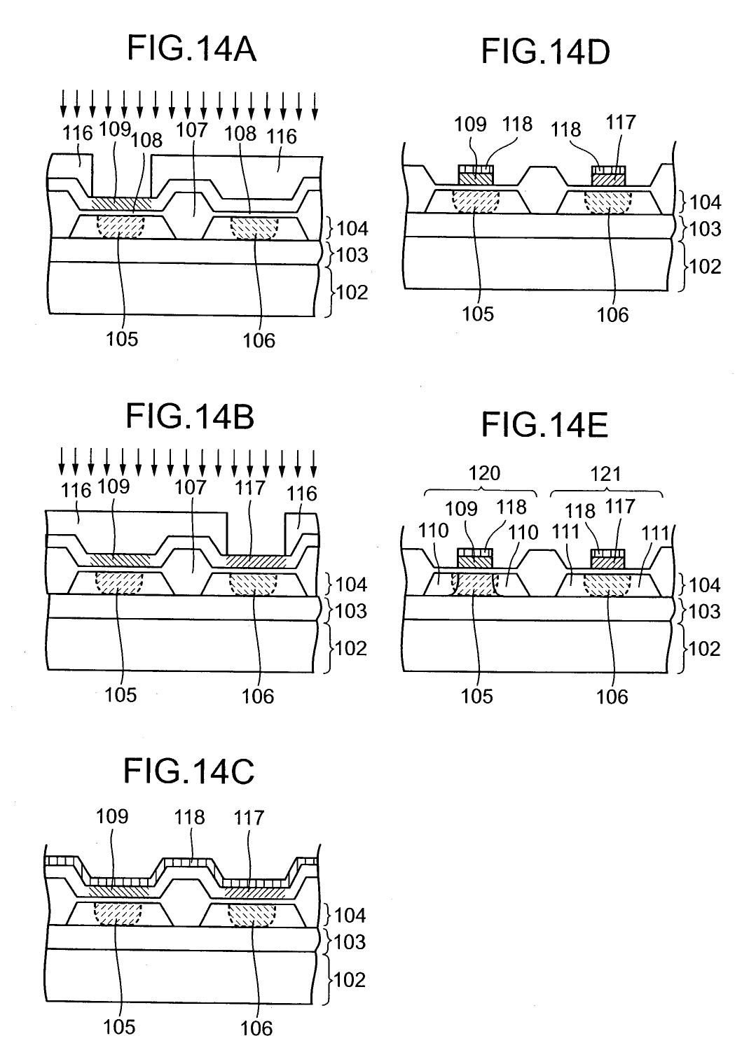

FIGS. 14A to 14E are process sectional views showing an embodiment of a method of manufacturing a semiconductor device that has the third structure of the present invention shown in FIG. 6. This manufacturing process is identical with the process illustrated in FIGS. 12A to 12G up through the step of FIG. 12E, namely, steps of forming well diffusion layers, forming a gate insulating film by thermal oxidation, and ion implantation to adjust the threshold voltage. Polycrystalline silicon is deposited onto the entire surface by CVD and an impurity is introduced to the resultant polycrystalline silicon film to give the film a conductivity. The polycrystalline silicon film is doped with impurities by ion implantation using photolithography in a way that makes the conductivity of a gate electrode of an NMOS different from the conductivity of a gate electrode of a PMOS. In FIG. 14A, after deposition of polycrystalline silicon, an N+ polycrystalline silicon film 109 is selectively formed first in the NMOS region by patterning using a photoresist film 116 and ion implantation of an n type impurity, phosphorus or arsenic. Then, as shown in FIG. 14B, the photoresist pattern is removed and the polycrystalline silicon film in the PMOS region is given a conductivity to selectively form a P+ polycrystalline silicon film 117 in the PMOS region. The P+ polycrystalline silicon film 117 is obtained in a manner similar to the N+ polycrystalline silicon film 109 in the NMOS region, by patterning using a photoresist film 116 and ion implantation of BF₂ as a p type impurity.

The photoresist pattern is removed. Then a high melting point metal silicide such as tungsten silicide is deposited on the polycrystalline silicon films in order to prevent the sheet resistance of gate electrodes from rising and to make high speed operation possible. Other than tungsten silicide, molybdenum silicide, titanium silicide, platinum silicide, or the like can be used. After patterning by photolithography, the films are etched to form gate electrodes (FIG. 14D). Thereafter, similar to FIG. 12F, high concentration impurity diffusion layers are formed in regions for forming sources and drains of the NMOS 120 and PMOS 121 to form the sources and drains. Then, though not shown in the drawing, an interlayer insulating film is formed by deposition, contact holes are formed, a metal wire is formed, and then a protective film is formed to cover the substrate and complete the semiconductor device.

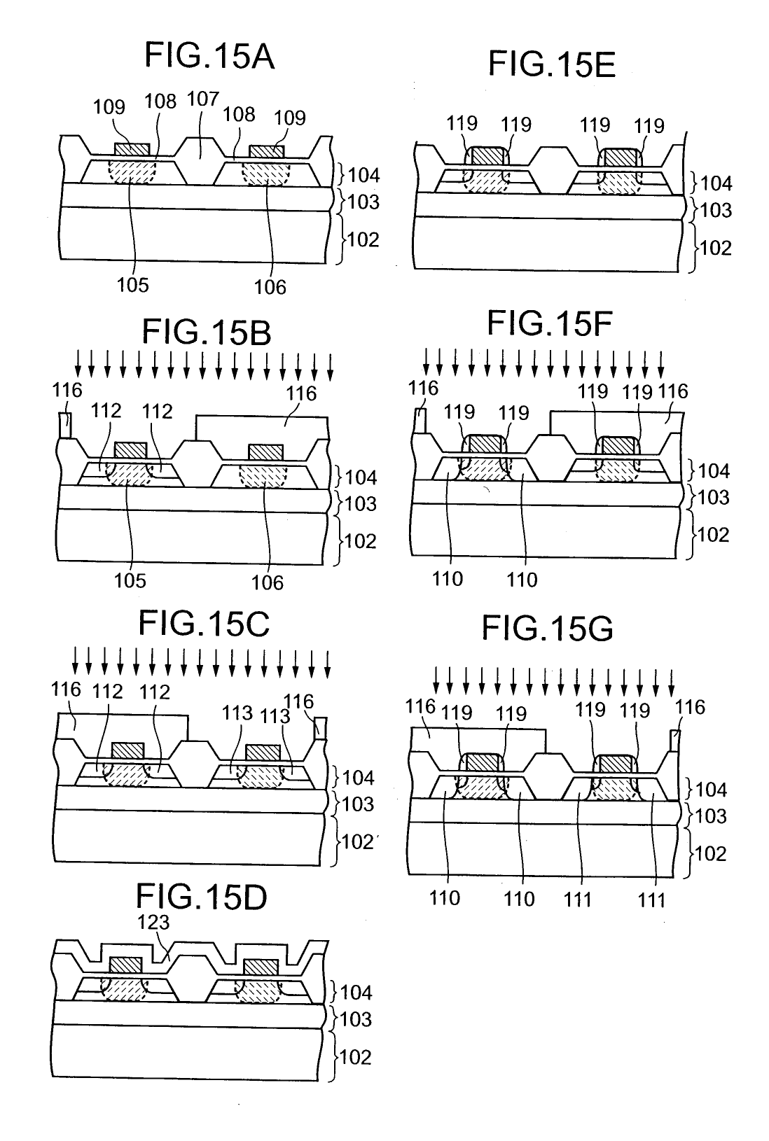

FIGS. 15A to 15G are process sectional views showing an embodiment of a method of manufacturing a semiconductor device that has the fourth structure of the present invention shown in FIG. 7. Steps of this manufacturing process up through formation of gate electrodes are identical with the steps illustrated in FIGS. 12A to 12F,or in FIGS. 13A to 13E. The substrate after the gate electrodes are formed is shown in section in FIG. 15A.

After the gate electrodes are formed from the N+ polycrystalline silicon film 109 as shown in FIG. 15A, a photoresist film 116 is patterned by photolithography so as to give the film 116 an opening that exposes the NMOS region as shown in FIG. 15B. Then, ion implantation is performed on the semiconductor thin film 104 to lightly dope the film 104 with an n type impurity, phosphorus or arsenic, and form N− diffusion layers 112 that are low concentration impurity diffusion layers of the NMOS. The dose is usually on the order of 10¹² to 10¹⁴ atoms/cm², and the impurity concentration in this case of the N− diffusion layers 112 is on the order of 10¹⁶ to 10¹⁸ atoms/cm³.

The photoresist pattern is then removed and a new photoresist film 116 is formed and patterned so as to give the film 116 an opening that exposes the PMOS region as shown in FIG. 15C. Then ion implantation is performed on the semiconductor thin film 104 to lightly dope the film 104 with a p type impurity, boron or BF₂, and form P− diffusion layers 113 that are low concentration impurity diffusion layers of the PMOS. Similar to the NMOS, the dose is usually on the order of 10¹² to 10¹⁴ atoms/cm², and the impurity concentration in this case of the P− diffusion layers 113 is on the order of 10¹⁶ to 10¹⁸ atoms/cm³.

Next, the photoresist pattern is removed and an insulating film 123 that later serves as side spacers is formed by CVD as shown in FIG. 15D. Then side spacers 119 are formed by anisotropic etching on side walls of the N+ polycrystalline silicon film 109 serving as gate electrodes as shown in FIG. 15E. Though it depends on etching conditions, the side spacers 119 are 0.2 to 0.5 μm in width in general.

After that, a photoresist film 116 is patterned by photolithography so as to give the film 116 an opening that exposes the NMOS region as shown in FIG. 15F. Then ion implantation is performed on the semiconductor thin film 104 to heavily dope the film 104 with an n type impurity, phosphorus or arsenic, and form N+ diffusion layers 110 that serve as source and drain regions.

The resist pattern is removed. Then, as in the NMOS region, a photoresist film 116 is formed and patterned so as to give the film 116 an opening that exposes the PMOS region. Ion implantation is performed to heavily dope the region with a p type impurity, boron or BF₂, and form P+ diffusion layers 111 that serve as the source and drain of the PMOS (FIG. 15G). The impurity concentration in the high concentration diffusion layers for forming the sources and drains of the NMOS and PMOS is generally about 5×10¹⁸ to 1 ×10²¹ atoms/cm³.

After that, though not shown in the drawing, an interlayer insulating film, a metal wire, and a protective film are formed as in the process illustrated in FIGS. 12A to 12G.

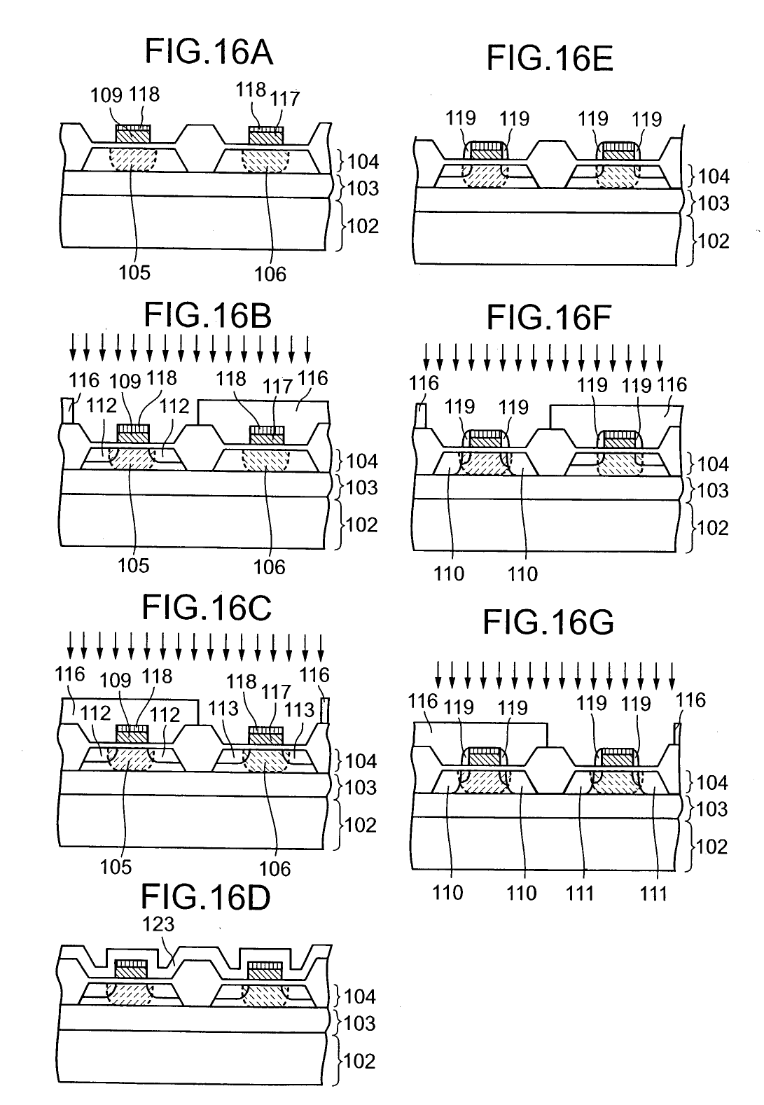

FIGS. 16A to 16G are process sectional views showing an embodiment of a method of manufacturing a semiconductor device that has the fifth structure of the present invention shown in FIG. 8. Steps of this manufacturing process up through formation of gate electrodes are identical with the steps illustrated in FIGS. 14A to 14D. The substrate after the gate electrodes are formed is shown in section in FIG. 16A. As shown in FIG. 16A, the gate electrodes have a laminate polycide structure in which a high melting point metal silicide film 118 such as a tungsten silicide film is laid on the N+ polycrystalline silicon film 109 and the P+ polycrystalline silicon film. The subsequent step is similar to the one shown in FIG. 15B.

A photoresist film 116 is patterned by photolithography so as to give the film 116 an opening that exposes the NMOS region as shown in FIG. 16B. Then ion implantation is performed on the semiconductor thin film 104 to lightly dope the film 104 with an n type impurity, phosphorus or arsenic, and form N− diffusion layers 112 that are low concentration impurity diffusion layers of the NMOS. The dose is usually on the order of 10¹² to 10¹⁴ atoms/cm², and the impurity concentration in this case of the N− diffusion layers 112 is on the order of 10¹⁶ to 10¹⁸ atoms/cm³.

The photoresist pattern is then removed and a new photoresist film 116 is formed and patterned so as to give the film 116 an opening that exposes the PMOS region as shown in FIG. 16C. Then ion implantation is performed on the semiconductor thin film 104 to lightly dope the film 104 with a p type impurity, boron or BF₂, and form P− diffusion layers 113 that are low concentration impurity diffusion layers of the PMOS. Similar to the NMOS, the dose is usually on the order of 10¹² to 10¹⁴ atoms/cm², and the impurity concentration in this case of the P− diffusion layers 113 is on the order of 10¹⁶ to 10¹⁸ atoms/cm³.

Next, the photoresist pattern is removed and an insulating film 123 that later serves as side spacers is formed by CVD as shown in FIG. 16D. Then side spacers 119 are formed by anisotropic etching on side walls of the laminate polycide gate electrodes, which are composed of the N+ polycrystalline silicon film 109, the P+ polycrystalline silicon film 117, and the high melting point metal silicide films, as shown in FIG. 16E. Though it depends on etching conditions, the side spacers 119 are 0.2 to 0.5 μm in width in general.

Thereafter, a photoresist film 116 is patterned by photolithography so as to give the film 116 an opening that exposes the NMOS region as shown in FIG. 16F. Then ion implantation is performed on the semiconductor thin film 104 to heavily dope the film 104 with an n type impurity, phosphorus or arsenic, and form N+ diffusion layers 110 that serve as a source region and a drain region.

Then the resist pattern is removed as shown in FIG. 16G. Similar to the NMOS region, a photoresist film 116 is formed and patterned so as to give the film 116 an opening that exposes the PMOS region. Ion implantation is performed to heavily dope the region with a p type impurity, boron or BF₂, and form P+ diffusion layers 111 that serve as the source and drain of the PMOS. The impurity concentration in the high concentration impurity diffusion layers for forming the sources and drains of the NMOS and PMOS is generally about 5×10¹⁹ to 1×10²¹ atoms/cm³.

After that, though not shown in the drawing, an interlayer insulating film, a metal wire, and a protective film are formed as in the process illustrated in FIGS. 12A to 12G.

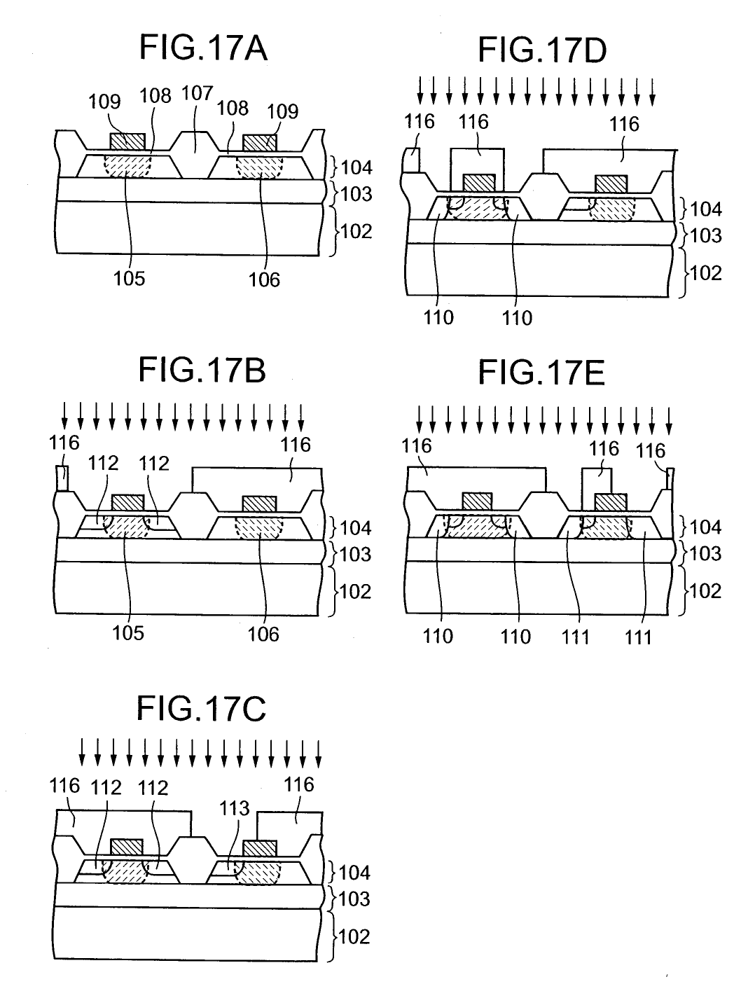

FIGS. 17A to 17E are process sectional views showing an embodiment of a method of manufacturing a semiconductor device that has the sixth structure of the present invention shown in FIG. 9. Steps of this manufacturing process up through formation of gate electrodes are identical with the steps illustrated in FIGS. 12A to 12F, or in FIGS. 13A to 13E, or in FIG. 15A. The substrate at this stage is shown in FIG. 17A.

After the gate electrodes are formed from the N+ polycrystalline silicon film 109 as shown in FIG. 17A, a photoresist film 116 is patterned by photolithography so as to give the film 116 an opening that exposes the NMOS region as shown in FIG. 17B. Then ion implantation is performed on the semiconductor thin film 104 to lightly dope the film 104 with an n type impurity, phosphorus or arsenic, and form N− diffusion layers 112 that are low concentration impurity diffusion layers of the NMOS. The dose is usually on the order of 10¹² to 10¹⁴ atoms/cm², and the impurity concentration in this case of the N− diffusion layers 112 is on the order of 10¹⁶ to 10¹⁸ atoms/cm³.

The N− diffusion layers 112 are formed in the source and the drain in FIG. 17B. However, whether to form an N− diffusion layer in a source and a drain each or in a drain alone can be chosen in accordance with the circuit structure.

The photoresist pattern is then removed and a new photoresist film 116 is formed and patterned so as to give the film 116 an opening that exposes the PMOS region as shown in FIG. 17C. Then ion implantation is performed on the semiconductor thin film 104 to lightly dope the film 104 with a p type impurity, boron or BF₂, and form a P− diffusion layer 113 that is a low concentration impurity diffusion layer of the PMOS. Similar to the NMOS, the dose is usually on the order of 10¹² to 10¹⁴ atoms/cm², and the impurity concentration in this case of the P− diffusion layer 113 is on the order of 10¹⁶ to 10¹⁸ atoms/cm³.

The P− diffusion layer 113 is formed in the drain alone in FIG. 17C. However, whether to form a P− diffusion layer in a source and a drain each or in a drain alone can be chosen in accordance with the circuit structure.

After that, a photoresist film 116 is patterned by photolithography so as to give the film 116 an opening that exposes the NMOS region as shown in FIG. 17D. Then ion implantation is performed on the semiconductor thin film 104 to heavily dope the film 104 with an n type impurity, phosphorus or arsenic, and form N+ diffusion layers 110 that serve as source and drain regions.

In forming the N+ diffusion layers, the photoresist film 116 is patterned so as to partially mask the source and drain adjacent to the gate electrode. The width of this mask determines the width of the N− diffusion layers, namely, the offset width, which is usually 0.5 μm or more and less than 10 μm. This drain extension structure is easy to modify by changing a mask pattern. Therefore, although the N− diffusion layers are formed in the source and drain in FIG. 17D, one N− diffusion layer may be formed on the drain side alone if necessary.

Similarly, the photoresist film 116 is patterned by photolithography so as to give the film 116 an opening that exposes the PMOS region as shown in FIG. 17E. Then ion implantation is performed to heavily dope the region with a p type impurity, boron or BF₂, and form P+ diffusion layers 111 that serve as the source and drain of the PMOS.

In forming the P+ diffusion layers, the photoresist film 116 is patterned so as to partially mask the source and drain adjacent to the gate electrode as in the NMOS region. The width of this mask determines the width of the P− diffusion layers, namely, the offset width, which is usually 0.5 μm or more and less than 10 μm. This drain extension structure is easy to modify by changing a mask pattern. Therefore, although one P− diffusion layer is formed only on the drain side in FIG. 17F, the P− diffusion layers may be formed in both the source and drain if necessary.

The impurity concentration in the high concentration impurity diffusion layers 110 and 111 for forming the sources and drains of the NMOS and PMOS is generally about 5×10¹⁹ to 1×10²¹ atoms/cm³. After that, though not shown in the drawing, an interlayer insulating film, a metal wire, and a protective film are formed as in the process illustrated in FIGS. 12A to 12G.

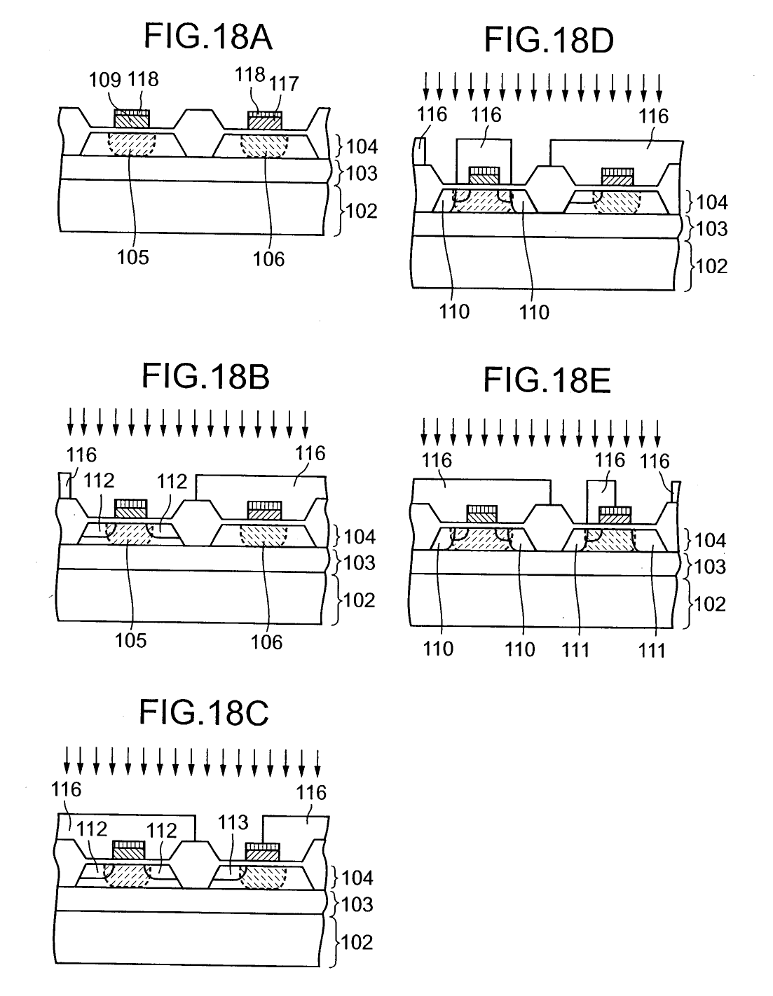

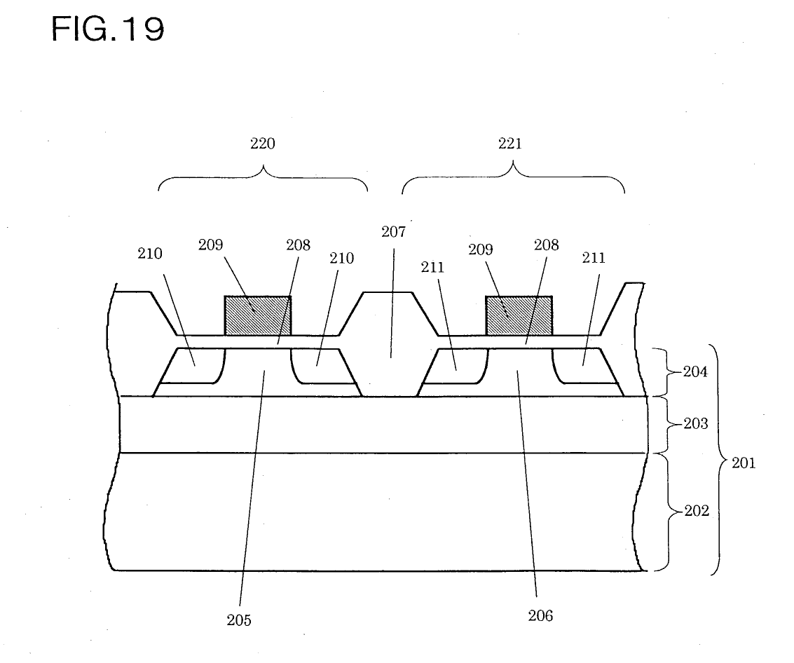

FIGS. 18A to 18E are process sectional views showing an embodiment of a method of manufacturing a semiconductor device that has the seventh structure of the present invention shown in FIG. 10. Steps of this manufacturing process up through formation of gate electrodes are identical with the steps illustrated in FIGS. 14A to 14D. The substrate after the gate electrodes are formed is shown in section in FIG. 18A. As shown in FIG. 18A, the gate electrodes have a laminate polycide structure in which a high melting point metal silicide film 118 such as a tungsten silicide film is laid on the N+ polycrystalline silicon film 109 and the P+ polycrystalline silicon film. The subsequent step is similar to the one shown in FIG. 17B.

A photoresist film 116 is patterned by photolithography so as to give the film 116 an opening that exposes the NMOS region as shown in FIG. 18B. Then ion implantation is performed on the semiconductor thin film 104 to lightly dope the film 104 with an n type impurity, phosphorus or arsenic, and form N− diffusion layers 112 that are low concentration impurity diffusion layers of the NMOS. The dose is usually on the order of 10¹² to 10¹⁴ atoms/cm², and the impurity concentration in this case of the N− diffusion layers 112 is on the order of 10¹⁶ to 10¹⁸ atoms/cm³.

The N− diffusion layers 112 are formed in the source and the drain in FIG. 18B. However, whether to form an N− diffusion layer in a source and a drain each or in a drain alone can be chosen in accordance with the circuit structure.

The photoresist pattern is then removed and a new photoresist film 116 is formed and patterned so as to give the film 116 an opening that exposes the PMOS region as shown in FIG. 18C. Then ion implantation is performed on the semiconductor thin film 104 to lightly dope the film 104 with a p type impurity, boron or BF₂, and form a P− diffusion layer 113 that is a low concentration impurity diffusion layer of the PMOS. Similar to the NMOS, the dose is usually on the order of 10¹² to 10¹⁴ atoms/cm², and the impurity concentration in this case of the P− diffusion layer 113 is on the order of 10¹⁶ to 10¹⁸ atoms/cm³.

The P− diffusion layer 113 is formed in the drain alone in FIG. 18C. However, whether to form a P− diffusion layer in a source and a drain each or in a drain alone can be chosen in accordance with the circuit structure.

After that, a photoresist film 116 is patterned by photolithography so as to give the film 116 an opening that exposes the NMOS region as shown in FIG. 18D. Then ion implantation is performed on the semiconductor thin film 104 to heavily dope the film 104 with an n type impurity, phosphorus or arsenic, and form N+ diffusion layers 110 that serve as source and drain regions.

In forming the N+ diffusion layers, the photoresist film 116 is patterned so as to partially mask the source and drain adjacent to the gate electrode. The width of this mask determines the width of the N− diffusion layers, namely, the offset width, which is usually 0.5 μm or more and less than 10 μm. This drain extension structure is easy to modify by changing a mask pattern. Therefore, although the N− diffusion layers are formed in the source and drain in FIG. 18D, one N− diffusion layer may be formed on the drain side alone if necessary.

Similarly, the photoresist film 116 is patterned by photolithography so as to give the film 116 an opening that exposes the PMOS region as shown in FIG. 18E. Then ion implantation is performed to heavily dope the region with a p type impurity, boron or BF₂, and form P+ diffusion layers 111 that serve as the source and drain of the PMOS.

In forming the P+ diffusion layers, the photoresist film 116 is patterned so as to partially mask the source and drain adjacent to the gate electrode as in the NMOS region. The width of this mask determines the width of the P− diffusion layers, namely, the offset width, which is usually 0.5 μm or more and less than 10 μm. This drain extension structure is easy to modify by changing a mask pattern. Therefore, although one P− diffusion layer is formed only on the drain side in FIG. 18F, the P− diffusion layers may be formed in both the source and drain.

The impurity concentration in the high concentration impurity diffusion layers 110 and 111 for forming the sources and drains of the NMOS and PMOS is generally about 5×10¹⁹ to 1×10²¹ atoms/cm³.

After that, though not shown in the drawing, an interlayer insulating film, a metal wire, and a protective film are formed as in the process illustrated in FIGS. 12A to 12G.

According to the present invention, in a semiconductor device which uses an SOI substrate and which has NMOS and PMOS transistors, a well diffusion layer is formed only in a body region below a gate electrode of each of the MOS transistors. This makes it easy to form N+ diffusion layers and P+ diffusion layers which are to serve as sources and drains, or a depletion layer resulted from pn junction, deep enough to reach a buried insulating film. Accordingly, a semiconductor device with reduced parasitic capacitance, which is a characteristic of SOI, can be obtained while raising the well concentration and increasing the thickness of its semiconductor thin film in order to reduce parasitic bipolar operation due to floating substrate effect and to prevent semiconductor supporting substrate bias from changing the threshold voltage.

What is claimed is:

1. A method of manufacturing a semiconductor device, comprising:
forming an element isolation region in the process of manufacturing a MOS transistor using an SOI substrate;
forming a well only in a body region below a gate electrode of the MOS transistor which is to be formed later in a semiconductor thin film;
forming a gate insulating film on the semiconductor thin film;
doping the semiconductor thin film with an impurity to control the threshold voltage;
depositing polycrystalline silicon on the semiconductor thin film and patterning the obtained polycrystalline silicon film to form the gate electrode;
lightly doping regions of the polycrystalline silicon film that are to serve as a source and drain of an NMOS transistor with an n type impurity to form first conductivity type low concentration impurity diffusion layers, the first conductivity type being the n type;
lightly doping regions of the polycrystalline silicon film that are to serve as a source and drain of a PMOS transistor with a p type impurity to form second conductivity type low concentration impurity diffusion layers, the second conductivity type being the p type;
forming an insulating film by deposition on the SOI substrate;
etching the insulating film by anisotropic dry etching to form a side spacer on a side wall of the gate electrode;
heavily doping the regions to serve as the source and drain of the NMOS transistor with an n type impurity to form first conductivity type high concentration impurity diffusion layers, the first conductivity type being the n type; and
heavily doping the regions to serve as the source and drain of the PMOS transistor with a p type impurity to form second conductivity type high concentration impurity diffusion layers, the second conductivity type being the p type.

2. A method of manufacturing a semiconductor device, comprising:
forming an element isolation region in the process of manufacturing a MOS transistor using an SOI substrate;
forming a well only in a body region below a gate electrode of the MOS transistor which is to be formed later in a semiconductor thin film;
forming a gate insulating film on the semiconductor thin film;
doping the semiconductor thin film with an impurity to control the threshold voltage;
depositing polycrystalline silicon on the semiconductor thin film;
doping a region of the polycrystalline silicon film that is to form an NMOS transistor with an n type impurity;
doping a region of the polycrystalline silicon film that is to form a PMOS transistor with a p type impurity;
forming a high melting point metal silicide film on the polycrystalline silicon film;
patterning the polycrystalline silicon film and the high melting point metal silicide film to form the gate electrode with a laminate structure;
lightly doping regions of the polycrystalline silicon film that are to serve as a source and drain of the NMOS transistor with an n type impurity to form first conductivity type low concentration impurity diffusion layers, the first conductivity type being the n type;
lightly doping regions of the polycrystalline silicon film that are to serve as a source and drain of the PMOS transistor with a p type impurity to form second conductivity type low concentration impurity diffusion layers, the second conductivity type being the p type;
forming an insulating film by deposition on the SOI substrate;
etching the insulating film by anisotropic dry etching to form a side spacer on a side wall of the gate electrode that is a laminate of the polycrystalline silicon film and the high melting point metal silicide film;
heavily doping the regions to serve as the source and drain of the NMOS transistor with an n type impurity to form first conductivity type high concentration impurity diffusion layers, the first conductivity type being the n type; and
heavily doping the regions to serve as the source and drain of the PMOS transistor with a p type impurity to form second conductivity type high concentration impurity diffusion layers, the second conductivity type being the p type.

3. A method of manufacturing a semiconductor device, comprising:
forming an element isolation region in the process of manufacturing a MOS transistor using an SOI substrate;
forming a well only in a body region below a gate electrode of the MOS transistor which is to be formed later in a semiconductor thin film;
forming a gate insulating film on the semiconductor thin film;
doping the semiconductor thin film with an impurity to control the threshold voltage;
depositing polycrystalline silicon on the semiconductor thin film and patterning the obtained polycrystalline silicon film to form the gate electrode;
selectively and lightly doping regions of the polycrystalline silicon film that are to serve as a source and drain of an NMOS transistor, or the drain region alone, with an n type impurity to form a first conductivity type low concentration impurity diffusion layer(s), the first conductivity type being the n type;
selectively and lightly doping regions of the polycrystalline silicon film that are to serve as a source and drain of a PMOS transistor, or the drain region alone, with a p type impurity to form a second conductivity type low concentration impurity diffusion layer(s), the second conductivity type being the p type;
selectively and heavily doping regions of the NMOS transistor where the source and the drain do not overlap the gate electrode flatly, or regions of the NMOS transistor where the source side overlaps the gate electrode flatly but not the drain side, with an n type impurity to form first conductivity type high concentration impurity diffusion layers, the first conductivity type being the n type; and
selectively and heavily doping regions of the PMOS transistor where the source and the drain do not overlap the gate electrode flatly, or regions of the PMOS transistor where the source side overlaps the gate electrode flatly but not the drain side, with a p type impurity to form second conductivity type high concentration impurity diffusion layers, the second conductivity type being the p type.

4. A method of manufacturing a semiconductor device, comprising:
forming an element isolation region in the process of manufacturing a MOS transistor using an SOI substrate;
forming a well only in a body region below a gate electrode of the MOS transistor which is to be formed later in a semiconductor thin film;
forming a gate insulating film on the semiconductor thin film;
doping the semiconductor thin film with an impurity to control the threshold voltage;
depositing polycrystalline silicon on the semiconductor thin film;
doping a region of the polycrystalline silicon film that is to form an NMOS transistor with an n type impurity;
doping a region of the polycrystalline silicon film that is to form a PMOS transistor with a p type impurity;
forming a high melting point metal silicide film on the polycrystalline silicon film;
patterning the polycrystalline silicon film and the high melting point metal silicide film to form the gate electrode with a laminate structure;
selectively and lightly doping regions of the polycrystalline silicon film that are to serve as a source and drain of an NMOS transistor, or the drain region alone, with an n type impurity to form a first conductivity type low concentration impurity diffusion layer(s), the first conductivity type being the n type;
selectively and lightly doping regions of the polycrystalline silicon film that are to serve as a source and drain of a PMOS transistor, or the drain region alone, with a p type impurity to form a second conductivity type low concentration impurity diffusion layer(s), the second conductivity type being the p type;
selectively and heavily doping regions of the NMOS transistor where the source and the drain do not overlap the gate electrode flatly, or regions of the NMOS transistor where the source side overlaps the gate electrode flatly but not the drain side, with an n type impurity to form first conductivity type high concentration impurity diffusion layers, the first conductivity type being the n type; and
selectively and heavily doping regions of the PMOS transistor where the source and the drain do not overlap the gate electrode flatly, or regions of the PMOS transistor where the source side overlaps the gate electrode flatly but not the drain side, with a p type impurity to form second conductivity type high concentration impurity diffusion layers, the second conductivity type being the p type.

5. A method of manufacturing a semiconductor device according to claims 1, wherein, when forming the well by patterning only in the body region below the gate electrode of the MOS transistor which is to be formed later in the semiconductor thin film, the region for forming the well overlaps the gate electrode by 0 to 2 μm.

6. A semiconductor device, comprising:
a MOS transistor which uses an SOI (silicon on insulator) substrate and which includes a semiconductor supporting substrate, a buried insulating film; and a semiconductor thin film, the buried insulating film being formed on the semiconductor supporting substrate, and the semiconductor thin film being formed on the buried insulating film,
wherein the MOS transistor has a well only in a body region below a gate electrode in the semiconductor thin film.

7. A semiconductor device according to claim 6, wherein a source and drain of the MOS transistor are high concentration impurity diffusion layers that overlap the gate electrode flatly, thereby giving the MOS transistor a single drain structure.

8. A semiconductor device according to claim 6, wherein the MOS transistor has a low concentration impurity diffusion layer where the source and the drain both overlap the gate electrode flatly and a high concentration impurity diffusion layer where the source and the drain both do not overlap the gate electrode flatly.

9. A semiconductor device according to claim 7, wherein the MOS transistor has a low concentration impurity diffusion layer where the drain alone overlaps the gate electrode flatly, or the source and the drain both overlap the gate electrode flatly, and a high concentration impurity diffusion layer where the drain alone does not overlap the gate electrode flatly, or the source and the drain both do not overlap the gate electrode flatly.

10. A semiconductor device according to claims 7, wherein the gate electrode of the MOS transistor is formed of a single layer of a first conductivity type polycrystalline silicon film, the first conductivity type being the n type.

11. A semiconductor device according to claims 7, wherein, when the MOS transistor is an NMOS transistor, the gate electrode of the MOS transistor takes a first conductivity type polycide structure that is a laminate of an n conductivity type polycrystalline silicon film and a high melting point metal silicide film, the high melting point metal silicide film being a molybdenum silicide film, a tungsten silicide film, a titanium silicide film, or a platinum silicide film, and
wherein, when the MOS transistor is a PMOS transistor, the gate electrode of the MOS transistor takes a second conductivity type polycide structure that is a laminate of a p type conductivity polycrystalline silicon film and the high melting point metal silicide film, the high melting point metal silicide film being a molybdenum silicide film, a tungsten silicide film, a titanium silicide film, or a platinum silicide film.

12. A semiconductor device according to claims 7,
wherein the MOS transistor has a T-shaped gate structure and the gate electrode of the MOS transistor forms the shape of a letter T by extending one end thereof in the W length direction toward the source region side and the drain region side, and
wherein a body contact region for fixing the electric potential of a body region below the gate electrode is placed on one end in the W length direction of the MOS transistor beyond the gate electrode.

13. A semiconductor device according to claims 7,
wherein the MOS transistor has an H-shaped gate structure and the gate electrode of the MOS transistor forms the shape of a letter H by extending both ends thereof in the W length direction toward the source region side and the drain region side, and
wherein a body contact region for fixing the electric potential of a body region below the gate electrode is placed on either end in the W length direction of the MOS transistor beyond the gate electrode.

14. A semiconductor device according to claims 7, wherein the MOS transistor has a source-body tie structure, and a body contact region for fixing the electric potential of a body region below the gate electrode is formed in a part of the source region that is joined to the body.

15. A semiconductor device according to claims 7, wherein the semiconductor thin film is 0.1 to 0.5 μm in thickness.

16. A semiconductor device according to claims 7, wherein the buried insulating film formed on the semiconductor supporting substrate is 0.1 to 0.5 μm in thickness.
